(19) United States
(12) Patent Application Publication
(10) Pub. No.: US 2026/0139163 A1
(43) Pub. Date: May 21, 2026

(54) PRESSURE-SENSITIVE ADHESIVE TAPE

(71) Applicant: NITTO DENKO CORPORATION, Osaka (JP)

(72) Inventors: Hiroto HAYASHI, Ibaraki-shi (JP); Mizuho CHIBA, Ibaraki-shi (JP)

(21) Appl. No.: 19/382,622

(22) Filed: Nov. 7, 2025

(30) Foreign Application Priority Data
Nov. 19, 2024 (JP) 2024-201892

(51) Int. Cl. C09J 7/38; C09J 4/00

(52) U.S. Cl. CPC C09J 7/38; C09J 4/00; C09J 2203/326; C09J 2301/302

(57) ABSTRACT

A pressure-sensitive adhesive tape, which can be easily peeled from a surface of an adherend after processing, further prevents fine particles from remaining on the surface of the adherend. The pressure-sensitive adhesive tape includes: a base material; and a pressure-sensitive adhesive layer formed of an active energy ray-curable pressure-sensitive adhesive. A ratio of a component having a weight-average molecular weight of 1,000 or less in a sol content of the pressure-sensitive adhesive layer after active energy ray irradiation is 20% or less. A pressure-sensitive adhesive strength of the pressure-sensitive adhesive layer after the active energy ray irradiation is 0.04 N/20 mm or less.

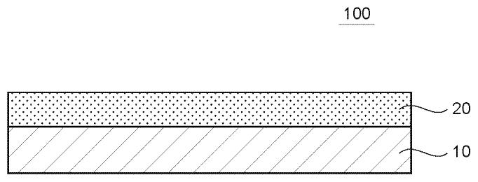

### CROSS-REFERENCE TO RELATED APPLICATION(S)

This application claims priority under 35 U.S.C. Section 119 to Japanese Patent Application No. 2024-201892 filed on Nov. 19, 2024, which is herein incorporated by reference.

### BACKGROUND

### Field

The present disclosure relates to a pressure-sensitive adhesive tape.

### Description of the Related Art

A pressure-sensitive adhesive tape has been widely used for the purposes of surface protection and fixation of an adherend. For example, in a processing process for a semiconductor wafer, the pressure-sensitive adhesive tape is used for appropriately holding the semiconductor wafer serving as the adherend in each of a backgrinding step and a dicing step. In recent years, miniaturization and thinning of a chip have been advanced, and hence the pressure-sensitive adhesive tape is required to have such a pressure-sensitive adhesive strength that the semiconductor wafer can be appropriately held even when thinly ground at the time of processing. The semiconductor wafer after the processing has a small thickness and thus tends to break easily, and hence the semiconductor wafer may break at the time of the peeling of the pressure-sensitive adhesive tape. Accordingly, a lightly peelable pressure-sensitive adhesive tape that can be easily peeled from an adherend after processing has been required. As such, a pressure-sensitive adhesive tape using a UV-curable pressure-sensitive adhesive has been proposed (for example, Japanese Patent Application Laid-open No. 2019-31620).

### SUMMARY

However, even when such a pressure-sensitive adhesive tape is used, fine foreign matter may remain on the surface of the wafer after the peeling of the pressure-sensitive adhesive tape. The fine foreign matter on the surface may have adverse effects on functions of a semiconductor wafer to be produced. In recent years, an increase in performance of a semiconductor has proceeded, and hence such a situation in which the fine foreign matter remains may particularly become a problem in the production of a high-performance semiconductor. Accordingly, a pressure-sensitive adhesive tape which can be easily peeled from a surface of an adherend after processing, and further prevents fine particles from remaining on the surface of the adherend, has been required.

1. According to at least one embodiment of the present disclosure, there is provided the pressure-sensitive adhesive tape, including: a base material; and a pressure-sensitive adhesive layer formed of an active energy ray-curable pressure-sensitive adhesive, wherein a ratio of a component having a weight-average molecular weight of 1,000 or less in a soluble content (sol content) of the pressure-sensitive adhesive layer after active energy ray irradiation is 20% or less, and wherein a pressure-sensitive adhesive strength of the pressure-sensitive adhesive layer after the active energy ray irradiation is 0.04 N/20 mm or less.

2. In the pressure-sensitive adhesive tape according to the above-mentioned item 1, the active energy ray-curable pressure-sensitive adhesive may be a water-dispersed pressure-sensitive adhesive.

3. In the pressure-sensitive adhesive tape according to the above-mentioned item 1 or 2, the active energy ray-curable pressure-sensitive adhesive may contain a water-dispersed acrylic polymer and an active energy ray-curable resin.

4. In the pressure-sensitive adhesive tape according to the above-mentioned item 3, the active energy ray-curable resin may contain urethane (meth)acrylate.

5. In the pressure-sensitive adhesive tape according to the above-mentioned item 3 or 4, a Hansen solubility parameter (HSP) value distance between the water-dispersed acrylic polymer and the active energy ray-curable resin may be 8 or less.

6. The pressure-sensitive adhesive tape according to any one of the above-mentioned items 1 to 5 may be used for semiconductor wafer processing.

According to at least one embodiment of the present disclosure, there can be provided the pressure-sensitive adhesive tape, which can be easily peeled from a surface of an adherend after processing, and further prevents fine particles from remaining on the surface of the adherend.

### BRIEF DESCRIPTION OF THE DRAWINGS

The FIGURE is a schematic sectional view of a pressure-sensitive adhesive tape according to at least one embodiment of the present disclosure.

### DETAILED DESCRIPTION

### A. Pressure-Sensitive Adhesive Tape

### A-1. Overall Configuration of Pressure-Sensitive Adhesive Tape

A pressure-sensitive adhesive tape according to at least one embodiment of the present disclosure includes: a base material; and a pressure-sensitive adhesive layer formed of an active energy ray-curable pressure-sensitive adhesive. A ratio of a component having a weight-average molecular weight of 1,000 or less (hereinafter also referred to as “low-molecular weight component”) in a sol content of the pressure-sensitive adhesive layer after active energy ray irradiation is 20% or less, and a pressure-sensitive adhesive strength of the pressure-sensitive adhesive layer after the active energy ray irradiation is 0.04 N/20 mm or less. With such pressure-sensitive adhesive tape, there can be provided the pressure-sensitive adhesive tape, which can be easily peeled from a surface of an adherend after processing, and further prevents fine particles from remaining on the surface of the adherend. It is conceived that the component having a weight-average molecular weight of 1,000 or less in the sol content of the pressure-sensitive adhesive layer after the active energy ray irradiation remains as fine particles on the surface of the adherend, which may serve as a cause of the contamination of the surface of the adherend with fine particles. When the ratio of the low-molecular weight component in the sol content is 20% or less, the contamination of the surface of the adherend with fine particles after the peeling of the pressure-sensitive adhesive tape can be prevented. In addition, the pressure-sensitive adhesive strength of the pressure-sensitive adhesive layer after the active energy ray irradiation is 0.04 N/20 mm or less. When the pressure-sensitive adhesive strength of the pressure-sensitive adhesive layer after the active energy ray irradiation is 0.04 N/20 mm or less, the pressure-sensitive adhesive tape can be more easily peeled from the adherend. As a result, a fine component derived from the pressure-sensitive adhesive layer can be prevented from remaining on the surface of the adherend at the time of the peeling.

The FIGURE is a schematic sectional view of a pressure-sensitive adhesive tape according to at least one embodiment of the present disclosure. A pressure-sensitive adhesive tape 100 includes a base material 20 and a pressure-sensitive adhesive layer 10 in the stated order. The pressure-sensitive adhesive tape 100 may further include any appropriate layer. For example, an intermediate layer (not shown) may be formed between the base material 20 and the pressure-sensitive adhesive layer 10. When the tape includes the intermediate layer, adhesiveness to an adherend having unevenness on its surface can be improved. In at least one embodiment of the present disclosure, an antistatic layer may be formed.

The ratio of the component having a weight-average molecular weight of 1,000 or less in the sol content of the pressure-sensitive adhesive layer after the active energy ray irradiation is 20% or less, preferably 15% or less, more preferably 10% or less, still more preferably 5% or less. The ratio of the component having a weight-average molecular weight of 1,000 or less in the sol content is preferably as small as possible, and may be 0%. Herein, a ratio of the component having a weight-average molecular weight of 1,000 or less in the sol content of the pressure-sensitive adhesive layer after the active energy ray irradiation refers to a ratio of the component having a weight-average molecular weight of 1,000 or less in a soluble content of the pressure-sensitive adhesive tape after the active energy ray irradiation when the soluble content is defined as 100. Specifically, the ratio refers to a value obtained by the following method.

### <Measurement of Low-Molecular Weight Component in Sol Content>

About 0.1 part by weight of a sample (the pressure-sensitive adhesive layer and the base material) is collected from the pressure-sensitive adhesive tape after the active energy ray irradiation. When a material used for the base material contains a component that may elute into ethyl acetate (e.g., an additive, such as a plasticizer or an antistatic agent), the base material is peeled, and 0.1 part by weight of only the pressure-sensitive adhesive layer is used. The collected sample is wrapped with a porous polytetrafluoroethylene film (e.g., a product available from the product name “NITOFLON (trademark) NTF1122” from Nitto Denko Corporation and a product equivalent thereto) having h an average pore diameter of 0.2 μm, and tied with a kite string. After that, the resultant is immersed in 50 mL of ethyl acetate at room temperature for 7 days so that the sol content is eluted out of the film. Next, the entire amount of the soluble content is collected into a screw tube, and a soluble content solution in the screw tube is left to stand at room temperature to be air-dried. After that, a solid content remaining in the screw tube is dissolved by adding tetrahydrofuran (THF) to the solid content so as to achieve a concentration of 3.3 g/L, and leaving the mixture to stand still for 1 day. After the solution has been filtered through a syringe filter, the molecular weight of the sol content is measured by a gel permeation chromatography (GPC) method under the following conditions to produce a molecular weight distribution curve. In the obtained molecular weight distribution curve, the area ratio of a component having a weight-average molecular weight (Mw) of 1,000 or less to the area of the entirety of the molecular weight distribution curve is calculated.

### <GPC Measurement Conditions>

Measurement conditions: sample introduction amount: 500 mg, column temperature: 40° C., flow rate: 1.0 mL/min
Apparatus: manufactured by Tosoh Corporation, product name: “HLC 8320GPC”

The gel fraction of the pressure-sensitive adhesive tape after the active energy ray irradiation is preferably 90% or more, more preferably 93% or more, still more preferably 95% or more. The gel fraction of the pressure-sensitive adhesive tape after the active energy ray irradiation is preferably as high as possible. When the gel fraction of the pressure-sensitive adhesive tape after the active energy ray irradiation falls within the above-mentioned ranges, the pressure-sensitive adhesive tape after the active energy ray irradiation can be easily peeled from the adherend. Herein, the gel fraction of the pressure-sensitive adhesive tape refers to a value measured by the following method.

### <Method of Measuring Gel Fraction>

The pressure-sensitive adhesive tape in which a polyester film subjected to release treatment is bonded to the pressure-sensitive adhesive layer is cut out into a size measuring 5 cm by 5 cm to provide a sample. The pressure-sensitive adhesive tape is irradiated with ultraviolet (UV) light (integrated light quantity: 460 mJ/cm² (365 nm conversion)) from a base material side. After that, the polyester film subjected to the release treatment is peeled from the sample. Next, about 0.1 part by weight of the sample is cut out from the sample after the irradiation with UV light. After that, the cut-out sample is wrapped with a porous polytetrafluoroethylene film (manufactured by Nitto Denko Corporation, product name: “NITOFLON (trademark) NTF1122”, porosity: 75%, thickness: 85 μm) having an average pore diameter of 0.2 μm whose weight has been measured in advance and a kite string (Wg₁) in a drawstring bag shape, and a total weight (Wg₂) is measured. Separately, the weight of the base material of the pressure-sensitive adhesive tape is calculated from its area and the specific gravity of a material for the base material (Wg₃). The bag is immersed in 50 mL of ethyl acetate and held at room temperature (about 23° C.) for 7 days so that only a sol component in the pressure-sensitive adhesive layer is eluted out of the film. After that, the bag is taken out from ethyl acetate, and ethyl acetate adhering to the outer surface of the bag is wiped off. Next, the bag is dried at 130° C. for 2 hours, and the weight (Wg₄) of the bag is measured. The measured values Wg₁ to Wg₄ are substituted into the following equation to calculate a gel fraction of the pressure-sensitive adhesive layer.

$$Gel fraction ( \% ) = [ ( {Wg}_{4} - {Wg}_{1} - {Wg}_{3} ) / ( {Wg}_{2} - {Wg}_{1} - {Wg}_{3} ) ]$$

When the base material contains a component that is soluble in ethyl acetate (e.g., an additive, such as a plasticizer or an antistatic agent), the gel fraction may be calculated by the following method.

The pressure-sensitive adhesive tape in which the polyester film subjected to the release treatment is bonded to the pressure-sensitive adhesive layer is cut out into a size measuring 5 cm by 5 cm to provide a sample. The pressure-sensitive adhesive tape is irradiated with UV light (UV) (integrated light quantity: 460 mJ/cm² (365 nm conversion)) from the base material side. After that, the polyester film subjected to the release treatment is peeled from the sample. Next, about 0.1 part by weight of the pressure-sensitive adhesive layer is collected from the sample after the irradiation with UV light. After that, the pressure-sensitive adhesive layer from which the base material has been peeled is wrapped with a porous polytetrafluoroethylene film (manufactured by Nitto Denko Corporation, product name: “NITOFLON (trademark) NTF1122”, porosity: 75%, thickness: 85 μm) having an average pore diameter of 0.2 μm whose weight has been measured in advance and a kite string (Wg_{A}) in a drawstring bag shape, and a total weight (Wg_{B}) is measured. The bag was immersed in 50 mL of ethyl acetate and held at room temperature (about 23° C.) for 7 days so that only a sol component in the pressure-sensitive adhesive layer is eluted out of the film. After that, the bag is taken out from ethyl acetate, and ethyl acetate adhering to the outer surface of the bag is wiped off. Next, the bag is dried at 130° C. for 2 hours, and the weight (Wg_{c}) of the bag is measured. The measured values Wg_{A} to Wg_{C} are substituted into the following equation to calculate a gel fraction of the pressure-sensitive adhesive layer.

$$Gel fraction ( \% ) = [ ( {Wg}_{c} - {Wg}_{A} ) / ( {Wg}_{B} - {Wg}_{A} - {Wg}_{C} ) ]$$

The pressure-sensitive adhesive strength of the pressure-sensitive adhesive tape after the active energy ray irradiation is 0.04 N/20 mm or less, preferably 0.03 N/20 mm or less, more preferably 0.02 N/20 mm or less. When the pressure-sensitive adhesive: strength after the active energy ray (e.g., UV) irradiation falls within the above-mentioned ranges, the pressure-sensitive adhesive tape having light peelability can be obtained. The pressure-sensitive adhesive strength after the active energy ray (e.g., UV) irradiation is preferably as small as possible. Herein, the pressure-sensitive adhesive strength of the pressure-sensitive adhesive tape after the active energy ray irradiation refers to a pressure-sensitive adhesive strength measured by the following method. The pressure-sensitive adhesive tape is bonded to a Si mirror wafer subjected to washing with toluene, ethanol, and toluene in the stated order, and drying. The resultant is stored at normal temperature for 30 minutes. Next, the pressure-sensitive adhesive tape is irradiated with UV (integrated light quantity: 460 mJ/cm²) with a high-pressure mercury lamp (e.g., manufactured by Nitto Seiki Co., Ltd., product name: “UM-810”). The pressure-sensitive adhesive strength is measured under the following conditions.

### <Pressure-Sensitive Adhesive Strength Measurement Conditions>

Tensile rate: 300 mm/min
Peel angle: 180° Temperature: 23° C.
Humidity: 50% RH
Tape width: 20 mm
Tape length: 80 mm

In the pressure-sensitive adhesive tape, the pressure-sensitive adhesive strength of the pressure-sensitive adhesive tape before the active energy ray irradiation is preferably 0.2 N/20 mm or more, more preferably 1.0 N/20 mm or more, still more preferably 2.0 N/20 mm or more. When the pressure-sensitive adhesive strength before the active energy ray irradiation falls within the above-mentioned ranges, the pressure-sensitive adhesive tape has sufficient adhesiveness to an adherend. In addition, the pressure-sensitive adhesive strength before the active energy ray irradiation is, for example, 20 N/20 mm or less. Herein, the pressure-sensitive adhesive strength of the pressure-sensitive adhesive tape before the active energy ray irradiation refers to a value measured by the following method. The pressure-sensitive adhesive tape is bonded to a Si mirror wafer subjected to washing with toluene, ethanol, and toluene in the stated order, and drying. The resultant is stored at normal temperature for 30 minutes. After that, the pressure-sensitive adhesive strength is measured under the following conditions.

### <Pressure-Sensitive Adhesive Strength Measurement Conditions>

Tensile rate: 300 mm/min
Peel angle: 180° Temperature: 23° C.
Humidity: 50% RH
Tape width: 20 mm
Tape length: 80 mm

The thickness of the pressure-sensitive adhesive tape according to at least one embodiment of the present disclosure may be set to any appropriate thickness. The thickness of the pressure-sensitive adhesive tape is preferably from 30 μm to 400 μm, more preferably from 40 μm to 300 μm, still more preferably from 50 μm to 200 μm.

### A-2. Base Material

The base material may be formed of any appropriate resin. Specific examples of the resin for forming the base material include polyester-based resins, such as polyethylene terephthalate (PET), polyethylene naphthalate (PEN), polybutylene terephthalate (PBT), and polybutylene naphthalate (PBN), polyolefin-based resins, such as an ethylene-vinyl acetate copolymer, an ethylene-methyl methacrylate copolymer, polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, polyether sulfone, and polyetheretherketone. Of those, polyolefin-based resins or polyester-based resins are preferred. Those resins each transmit UV light, and hence can each form the pressure-sensitive adhesive layer with a UV-curable pressure-sensitive adhesive to provide the pressure-sensitive adhesive tape having light peelability.

The base material may further contain other components to the extent that the effects of the present disclosure are not impaired. Examples of the other components include an antioxidant, a UV absorber, a light stabilizer, a heat stabilizer, and an antistatic agent. With regard to the kind and usage amount of the other components, the components may be used in any appropriate amount in accordance with purposes.

The thickness of the base material is preferably from 30 μm to 200 μm, more preferably from 40 μm to 180 μm, still more preferably from 45 μm to 180 μm.

### A-3. Pressure-Sensitive Adhesive Layer

The pressure-sensitive adhesive layer of the pressure-sensitive adhesive tape according to at least one embodiment of the present disclosure is formed of the active energy ray-curable pressure-sensitive adhesive. A typical example of the active energy ray-curable pressure-sensitive adhesive is a UV-curable pressure-sensitive adhesive. The active energy ray-curable pressure-sensitive adhesive is preferably a water-dispersed pressure-sensitive adhesive. A pressure-sensitive adhesive containing a water-dispersed acrylic polymer, an active energy ray-curable resin, and a photopolymerization initiator is preferably used as the water-dispersed pressure-sensitive adhesive. When such pressure-sensitive adhesive is used, the pressure-sensitive adhesive tape has an excellent pressure-sensitive adhesive strength, and hence can exhibit excellent adhesiveness to an adherend. While such pressure-sensitive adhesive is an aqueous pressure-sensitive adhesive composition, the pressure-sensitive adhesive has an excellent pressure-sensitive adhesive strength, and can achieve both of adhesiveness to an adherend and light peelability. Accordingly, there can be provided a pressure-sensitive adhesive, which can reduce an environmental load by reducing the usage amount of a solvent, and can be suitably used in a processing process for a semiconductor wafer.

A distance between Hansen solubility parameter (HSP) values of the water-dispersed acrylic polymer and the active energy ray-curable resin is preferably 8 or less, more preferably 7.5 or less, still more preferably 7.0 or less. The distance between the HSP values of the water-dispersed acrylic polymer and the active energy ray-curable resin is, for example, 0 or more. When the distance between the HSP values of the water-dispersed acrylic polymer and the active energy ray-curable resin falls within the above-mentioned ranges, compatibility between the water-dispersed acrylic polymer and the active energy ray-curable resin is satisfactory, and the ratio of the low-molecular weight component present after the active energy ray irradiation can be reduced. Accordingly, a light-peelable pressure-sensitive adhesive tape is obtained. Further, fine particles are prevented from remaining on the adherend, and hence the contamination of the adherend with the fine particles can be prevented.

The Hansen solubility parameter is represented by a vector obtained by dividing a Hildebrand solubility parameter into three components, that is, a dispersion force (δD), a permanent dipole intermolecular force (δP), and a hydrogen bonding force (δH), and plotting the components in a three-dimensional space. Components whose vectors obtained as described above are similar to each other can be judged to have high solubilities to each other. That is, a degree of similarity between the solubilities can be judged from a distance between HSP values (HSP value distance) of the components. The definition and calculation of Hansen solubility parameters are described in Charles M. Hansen, Hansen Solubility Parameters: A Users Handbook (CRC Press, 2007). The HSP values are known for various resins and solvents, and the values may be used as they are, or values calculated with computer software “Hansen Solubility Parameters in Practice” (HSPiP) may be used. The HSPiP also includes databases for resins and solvents.

The HSP values of an acrylic polymer and an active energy ray-curable resin whose HSP values are not known may be measured by the following method. In a sealable container, the acrylic polymer or the active energy ray-curable resin to be measured is loaded into each of about 20 kinds of solvents having different HSP values at such a concentration that the acrylic polymer or the active energy ray-curable resin is dissolved in about half of the 20 kinds and is not dissolved in about half thereof. Next, the container is shaken by hand so that the acrylic polymer or the active energy ray-curable resin and the solvent were sufficiently mixed. Next, the container is left to stand still under a room temperature environment (23° C.) for 24 hours. After that, the container is visually observed. A case in which a precipitate or an aggregate is present in the container is defined as “not dissolved” and a case in which the precipitate and the aggregate are absent therein is defined as “dissolved.” The test is performed on a plurality of solvents, and from the obtained test results, a sphere (Hansen sphere) that includes coordinates of solvents, each of which has dissolved a target substance, and that is free of coordinates of solvents, each of which has not dissolved the target substance, is drawn in a Hansen space. The obtained numerical value is input into the above-mentioned calculation software to calculate HSP values of the acrylic polymer and the UV-curable resin from the following equation. Herein, the calculation of the HSP value is performed by using cyclohexane, toluene, chloroform, 4-methyl-2-pentanone, ethyl acetate, cyclohexanone, 1,1,2,2-tetrabromoethane, acetone, N-methyl-2-pyrrolidone, benzyl alcohol, 1-butanol, acetic acid, 2-methoxy-ethanol, γ-butyrolactone, N,N-dimethylformamide, ethanol, N-methylformamide, ethanolamine, formamide, or 2-propanol.

$$Ra = {[ 4 \times {( δ {d}_{p} - δ {d}_{r} )}^{2} + {( δ {p}_{p} - δ {p}_{r} )}^{2} + {( δ {h}_{p} - δ {h}_{r} )}^{2} ]}^{1 / 2}$$

Next, the distance (Ra) between the HSP values of the acrylic polymer and the active energy ray-curable resin is calculated by the following equation from the resultant dispersion force (δdₚ), permanent dipole intermolecular force (δpₚ), and hydrogen bonding force (δhₚ) of the acrylic polymer, and dispersion force (δdᵣ), permanent dipole intermolecular force (δpᵣ), and hydrogen bonding force (δhᵣ) of the active energy ray-curable resin.

$$HSP value = √ ( δ D \hat{} 2 + δ P \hat{} 2 + δ H \hat{} 2 )$$

### A-3-1. Water-Dispersed Acrylic Polymer

The water-dispersed acrylic polymer (hereinafter also referred to as the “acrylic polymer”) may be obtained by subjecting any appropriate monomer component to emulsion polymerization in water. That is, the water-dispersed acrylic polymer is an emulsion of the acrylic polymer. The average particle diameter of the acrylic polymer emulsion is preferably from 80 nm to 400 nm, more preferably from 100 nm to 300 nm, still more preferably from 100 nm to 200 nm. Herein, the average particle diameter of the water-dispersed acrylic polymer refers to a volume-based median diameter (D50) measured by a laser diffraction-scattering method.

In at least one embodiment of the present disclosure, the water-dispersed acrylic polymer is preferably a polymer having a core-shell type structure (hereinafter also referred to as a “core-shell polymer”). When the water-dispersed acrylic polymer serving as the core-shell polymer is used, there can be provided a pressure-sensitive adhesive, which has a more excellent pressure-sensitive adhesive strength before the active energy ray irradiation, and can achieve both adhesiveness to an adherend and light peelability.

The water-dispersed acrylic polymer serving as a core-shell polymer is obtained by subjecting any appropriate monomer component to emulsion polymerization in a stepwise manner. The water-dispersed acrylic polymer may be obtained by, for example, so-called seed polymerization including subjecting a monomer composition for forming a core portion to emulsion polymerization by any appropriate method, and then subjecting a monomer composition for forming a shell portion to emulsion polymerization in the presence of the generated polymer particles serving as a core portion.

The core ratio of the water-dispersed acrylic polymer serving as a core-shell polymer is preferably 5 wt % or more, more preferably 10 wt % or more. When a weight ratio between the core portion and the shell portion falls within the above-mentioned ranges, there can be provided the water-dispersed pressure-sensitive adhesive composition that has an excellent pressure-sensitive adhesive strength, and that can achieve both adhesiveness to an adherend and light peelability.

The core-shell polymer preferably includes a shell portion having a glass transition temperature Tg of −10° C. or more, and a core portion having a glass transition temperature Tg of less than −10° C. When such core-shell polymer is used, there can be obtained the pressure-sensitive adhesive tape that has an excellent pressure-sensitive adhesive strength before the active energy ray irradiation, and that can be peeled without breakage of an adherend after the active energy ray irradiation.

The glass transition temperature Tg of the shell portion is preferably −10° C. or more, more preferably −5° C. or more, still more preferably 0° C. or more. The glass transition temperature Tg of the shell portion is, for example, 50° C. or less. The glass transition temperature Tg of the core portion is preferably less than −10° C., more preferably −20° C. or less, still more preferably −30° C. or less, particularly preferably −35° C. or less. The glass transition temperature Tg of the core portion is, for example, −60° C. or more. When the glass transition temperatures Tg of the core portion and the shell portion fall within the above-mentioned ranges, there can be provided the pressure-sensitive adhesive tape having a satisfactory pressure-sensitive adhesive property before the active energy ray irradiation, and satisfactory peelability after the active energy ray irradiation.

Herein, the glass transition temperature of the water-dispersed acrylic polymer refers to a theoretical value calculated by Fox's equation from monomer units for forming each polymer and ratios thereof. The theoretical glass transition temperature determined by Fox's equation may be consistent with an actually measured glass transition temperature determined by a method, such as differential scanning calorimetry (DSC) or dynamic viscoelasticity measurement. As described later, when the theoretical value cannot be calculated, the actually measured glass transition temperature may be used.

As described below, Fox's equation is a relational equation between the Tg of an acrylic polymer and the glass transition temperature Tgi of a homopolymer obtained by homopolymerizing each of monomers for forming the acrylic polymer:

$$1 / Tg = \sum ( Wi / Tgi )$$

where Tg represents the glass transition temperature (unit: K) of the acrylic polymer, Wi represents the weight fraction (copolymerization ratio on a weight basis) of a monomer “i” in the acrylic polymer, and Tgi represents the glass transition temperature (unit: K) of the homopolymer of the monomer “i”.

A value described in any appropriate material may be used as the glass transition temperature of the homopolymer to be used in the calculation of the Tg. For example, for monomers listed below, the following values are used as glass transition temperatures of the homopolymers of the monomers.

| | | |
|---|---|---|
| 2-Ethylhexyl acrylate | −70° | C. |
| Methyl methacrylate | 8° | C. |
| Acrylic acid | 106° | C. |
| 2-Acryloyloxyethyl succinate | −40° | C. |
| 4-Hydroxybutyl acrylate | −40° | C. |
| N-Acryloylomorpholine | 145° | C. |
| Butyl acrylate | −55° | C. |
| Ethyl acrylate | −20° | C. |
| 2-Hydroxyethyl acrylate | −15° | C. |

A numerical value described in, for example, “Polymer Handbook” (3rd edition, John Wiley & Sons, Inc., 1989) may be used as the glass transition temperature of the homopolymer of a monomer except those listed above. When a plurality of kinds of values are described, the highest value is adopted.

A value obtained by a measurement method described in Japanese Patent Application Laid-open No. 2007-51271 may be used for such a monomer that the glass transition temperature of a homopolymer thereof is not described in the above-mentioned Polymer Handbook. Specifically, 100 parts by weight of the monomer, 0.2 part by weight of azobisisobutyronitrile, and 200 parts by weight of ethyl acetate serving as a polymerization solvent are loaded into a reactor including a temperature gauge, a stirring machine, a nitrogen-introducing tube, and a reflux condenser, and are stirred for 1 hour while a nitrogen gas is flowed in the reactor. After oxygen in a polymerization system has been removed as described above, a temperature in the reactor is increased to 63° C. and the mixture is subjected to a reaction for 10 hours. Next, the resultant is cooled to room temperature to provide a homopolymer solution having a solid content concentration of 33 wt %. Next, the homopolymer solution is cast onto a release liner, and is dried to produce a test sample having a thickness of about 2 mm (sheet-shaped homopolymer). The test sample is punched into a disc shape having a diameter of 7.9 mm. The disc is sandwiched between parallel plates, and its viscoelasticity is measured with a viscoelasticity tester (ARES, manufactured by Rheometric Scientific, Inc.) in the temperature region of −70° C. to 150° C. at a rate of temperature increase of 5° C./min by a shear mode while a shear strain having a frequency of 1 Hz is applied to the disc. The peak top temperature of the tan δ of the disc is defined as the Tg of the homopolymer.

### A-3-1-1. Monomer Component

The composition of the monomer composition to be used in the formation of each of the core portion and the shell portion may be adjusted so that the core portion or shell portion having any appropriate glass transition temperature is formed. For example, a monomer only needs to be selected based on Fox's equation described above so that the core portion or the shell portion has a designed glass transition temperature Tg, followed by emulsion polymerization.

Any appropriate acrylic monomer is used as the monomer component. A (meth)acrylic acid alkyl ester is used as a typical monomer component. Specific examples of the (meth)acrylic acid alkyl ester include (meth)acrylic acid C1 to C20 alkyl esters, such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicoscyl (meth)acrylate. The (meth)acrylic acid alkyl esters may be used alone or in combination thereof. Herein, the term “(meth)acryl” refers to acryl and/or methacryl.

The monomer composition may further contain any appropriate other monomer copolymerizable with the (meth)acrylic acid alkyl ester. Examples thereof include: carboxyl group-containing monomers, such as acrylic acid and methacrylic acid; acid anhydride monomers, such maleic anhydride as and itaconic anhydride; hydroxyl group-containing monomers including hydroxyalkyl (meth)acrylates, such as 2-hydroxyethyl (meth)acrylate, 2-hydroxypropyl (meth)acrylate, 2-hydroxybutyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methyl (meth)acrylate; sulfonic acid group-containing monomers, such as styrenesulfonic acid and allylsulfonic acid; (N-substituted) amide-based monomers, such as diacetone acrylamide, (meth)acrylamide, and N,N-dimethyl (meth)acrylamide; aminoalkyl (meth)acrylate-based monomers such as aminoethyl (meth)acrylate; alkoxyalkyl (meth)acrylate-based monomers such as methoxyethyl (meth)acrylate; maleimide-based monomers, such as N-cyclohexylmaleimide and N-isopropylmaleimide; itaconimide-based monomers, such as N-methylitaconimide and N-ethylitaconimide; succinimide-based monomers; vinyl-based monomers, such as vinyl acetate, vinyl propionate, N-vinylpyrrolidone, and methylvinylpyrrolidone; cyanoacrylate monomers, such as acrylonitrile and methacrylonitrile; epoxy group-containing acrylic monomers such as glycidyl (meth)acrylate; glycol-based acrylic ester monomers, such as polyethylene glycol (meth)acrylate and polypropylene glycol (meth)acrylate; acrylic acid ester-based monomers each having a heterocycle, a halogen atom, or a silicon atom, such as tetrahydrofurfuryl (meth)acrylate, fluorine (meth)acrylate, and silicone (meth)acrylate; olefin-based monomers, such as isoprene, butadiene, and isobutylene; and vinyl ether-based monomers such as vinyl ether. The incorporation of those monomer components can modify, for example, cohesive strength, heat resistance, or cross-linkability. Those monomer components may be used alone or in combination thereof.

In at least one embodiment of the present disclosure, an amide group-containing monomer is preferably used as a monomer component for forming the shell portion. Specific examples of the amide group-containing monomer include: acrylamide-based monomers, such as (meth)acrylamide, N,N-dimethyl (meth)acrylamide, N,N-diethyl (meth)acrylamide, N-isopropyl acrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers, such as N-(meth)acryloylmorpholine, N-(meth)acryloylpiperidine, and N-(meth)acryloylpyrrolidine; and N-vinyl group-containing lactam-based monomers, such as N-vinylpyrrolidone and N-vinyl-ε-caprolactam. Of those, N-(meth)acryloylmorpholine, N,N-diethyl (meth)acrylamide, and N-isopropyl acrylamide are preferred, and N-acryloylmorpholine is more preferred. When the amide group-containing monomer is used as the monomer to be used in the polymerization of the shell portion, the initial pressure-sensitive adhesive strength of the pressure-sensitive adhesive layer can be improved. The content ratio of the amide group-containing monomer in all monomers for forming the shell portion is, for example, from 0.01 wt % to 10 wt %, preferably from 0.1 wt % to 7 wt %.

In at least one embodiment of the present disclosure, the acrylic polymer is preferably a polymer obtained by polymerizing a monomer composition containing a carboxyl group-containing monomer represented by the formula (1) as a monomer component. When the acrylic polymer is a core-shell polymer, the carboxyl group-containing monomer represented by the formula (1) may be incorporated into only the monomer composition to be used in the polymerization of the core portion, may be incorporated into only the monomer composition to be used in the polymerization of the shell portion, or may be incorporated into the monomer composition to be used in the polymerization of the core portion and the monomer composition to be used in the polymerization of the shell portion. The carboxyl group-containing monomers may be used alone or in combination thereof.

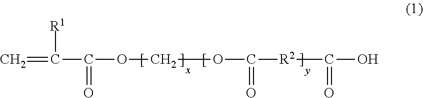

In the formula, R¹ represents a hydrogen atom or a methyl group, R² represents a divalent hydrocarbon group, “x” represents an integer from 1 to 20, and “y” represents 0 or 1.

R¹ represents a hydrogen atom or a methyl group. “x” represents an integer from 1 to 20, preferably an integer from 1 to 10, more preferably an integer from 1 to 8. “y” represents 0 or 1. R² represents a divalent hydrocarbon group. Examples of the divalent hydrocarbon group include: saturated aliphatic hydrocarbon groups such as an alkylene group; saturated alicyclic hydrocarbon groups such as a cycloalkylene group; aromatic hydrocarbon groups such as a phenylene group; unsaturated aliphatic hydrocarbon groups; and unsaturated alicyclic hydrocarbon groups. R² represents preferably a linear or branched alkylene group, or a cycloalkylene group, more preferably a linear or branched alkylene group having 1 to 20 carbon atoms, or a cycloalkylene group, still more preferably a linear or branched alkylene group having 1 to 10 carbon atoms, or a cycloalkylene group. When “x” falls within the above-mentioned ranges and R² represents the above-mentioned divalent hydrocarbon group, a pressure-sensitive adhesive excellent in dispersion stability and applicability can be obtained.

Specific examples of the carboxyl group-containing monomer represented by the formula (1) include 2-acryloyloxyethyl succinate, 2-methacryloyloxyethyl succinate, 2-acryloyloxyethyl hexahydrophthalate, ω-carboxy-polycaprolactone (n≈2) monoacrylate, and 2-methacryloyloxyethyl hexahydrophthalate.

A commercially available product may be used as the carboxyl group-containing monomer represented by the formula (1). Examples of the commercially available product include: products available under the product names “HOA-MS”, “Light Ester HO-MS(N)”, and “Light Acrylate HOA-HH(N)” from Kyoeisha Chemical Co., Ltd.; and a product available under the product name “ARONIX M-5300” from Toagosei Co., Ltd.

The content ratio of the carboxyl group-containing monomer represented by the formula (1) is preferably from 3 parts by weight to 30 parts by weight, more preferably from 4 parts by weight to 25 parts by weight, still more preferably from 4 parts by weight to 20 parts by weight, particularly preferably from 6 parts by weight to 15 parts by weight with respect to 100 parts by weight of monomer components (in the case of the core-shell polymer, monomer components to be used in the polymerization of the core portion or monomer components to be used in the polymerization of the shell portion). When the content ratio of the carboxyl group-containing monomer represented by the formula (1) falls within the above-mentioned ranges, a pressure-sensitive adhesive excellent in dispersion stability and applicability can be obtained.

### A-3-2. Surfactant

Any appropriate surfactant may be used as a surfactant. A reactive surfactant may be preferably used. The reactive surfactant has a radically polymerizable functional group (e.g., a radical reactive group, such as an ethenyl group, a propenyl group, an allyl group, or an allyl ether group) in a molecule thereof while having a function as a surfactant. When the reactive surfactant is used, the contamination of an adherend with the pressure-sensitive adhesive in which the water-dispersed acrylic polymer is used can be reduced, and the pressure-sensitive adhesive strength of the pressure-sensitive adhesive composition before radiation irradiation treatment can be improved. In addition, the water resistance of the pressure-sensitive adhesive tape (e.g., the pressure-sensitive adhesive layer) using the pressure-sensitive adhesive composition is improved, and hence the peeling of the pressure-sensitive adhesive tape can be prevented even when the tape is brought into contact with water at the time of processing.

The reactive surfactant is, for example, a surfactant obtained by introducing a radically polymerizable functional group (radical reactive group), such as a propenyl group or an allyl ether group, into any appropriate surfactant (e.g., an anionic surfactant or a nonionic surfactant). The reactive surfactant has a radically polymerizable functional group according to an ethylenically unsaturated double bond, and can reduce the saturated water absorption ratio of the pressure-sensitive adhesive layer to be formed as compared to a nonreactive surfactant. Further, the reactive surfactants to be preferably used may be used alone or in combination thereof from the viewpoints of the stability of a water dispersion liquid and the durability of the pressure-sensitive adhesive layer.

Specific examples of the anionic surfactant include: higher fatty acid salts such as sodium oleate; alkylaryl sulfonic acid salts such as sodium dodecylbenzene sulfonate; alkyl sulfuric acid ester salts, such as sodium lauryl sulfate and ammonium lauryl sulfate; polyoxyethylene alkyl ether sulfuric acid ester salts such as sodium polyoxyethylene lauryl ether sulfate; polyoxyethylene alkylaryl ether sulfuric acid ester salts such as sodium polyoxyethylene nonylphenyl ether sulfate; alkyl sulfosuccinic acid ester salts and derivatives thereof, such as sodium monooctyl sulfosuccinate, sodium dioctyl sulfosuccinate, and sodium polyoxyethylene lauryl sulfosuccinate; and polyoxyethylene distyrenated phenyl ether sulfuric acid ester salts. Specific examples of the nonionic surfactant include: polyoxyethylene alkyl ethers, such as polyoxyethylene lauryl ether and polyoxyethylene stearyl ether; polyoxyethylene alkylphenyl ethers, such as polyoxyethylene octylphenyl ether and polyoxyethylene nonylphenyl ether; sorbitan higher fatty acid esters, such as sorbitan monolaurate, sorbitan monostearate, and sorbitan trioleate; polyoxyethylene sorbitan higher fatty acid esters such as polyoxyethylene sorbitan monolaurate; polyoxyethylene higher fatty acid esters, such as polyoxyethylene monolaurate and polyoxyethylene monostearate; glycerin higher fatty acid esters, such as oleic acid monoglyceride and stearic acid monoglyceride; and a polyoxyethylene-polyoxypropylene-block copolymer and polyoxyethylene distyrenated phenyl ether.

A commercially available product may be used as the reactive surfactant. Specific examples of the anionic reactive surfactant include: alkyl ether-based reactive surfactants, such as products available under the product names “AQUALON KH-05”, “AQUALON KH-10”, and “AQUALON KH-20” from DKS Co. Ltd., products available under the product names “ADEKA REASOAP SR-10N” and “ADEKA REASOAP SR-20N” from Asahi Denka Co., Ltd., and a product available under the product name “LATEMUL PD-104” from Kao Corporation; sulfosuccinic acid ester-based reactive surfactants, such as products available under the product names “LATEMUL S-120”, “LATEMUL S-120A”, “LATEMUL S-180P”, and “LATEMUL S-180A” from Kao Corporation, and a product available under the product name “ELEMINOL JS-20” from Sanyo Chemical Industries, Ltd.; alkylphenyl ether-based or alkylphenyl ester-based reactive surfactants, such as products available under the product names “AQUALON H-2855A”, “AQUALON H-3855B”, “AQUALON H-3855C”, “AQUALON H-3856”, “AQUALON HS-05”, “AQUALON HS-10”, “AQUALON HS-20”, “AQUALON HS-30”, “AQUALON BC-05”, “AQUALON BC-10”, and “AQUALON BC-20” from DKS Co. Ltd., and products available under the product names “ADEKA REASOAP SDX-222”, “ADEKA REASOAP SDX-223”, “ADEKA REASOAP SDX-232”, “ADEKA REASOAP SDX-233”, “ADEKA REASOAP SDX-259”, “ADEKA REASOAP SE-10N”, and “ADEKA REASOAP SE-20N” from Asahi Denka Co., Ltd.; (meth)acrylate sulfuric acid ester-based reactive surfactants, such as products available under the product names “ANTOX MS-60” and “ANTOX MS-2N” from Nippon Nyukazai Co., Ltd., and a product available under the product name “ELEMINOL RS-30” from Sanyo Chemical Industries, Ltd.; phosphoric acid ester-based reactive surfactants, such as a product available under the product name “H-3330PL” from DKS Co. Ltd. and a product available under the product name “ADEKA REASOAP PP-70” from Asahi Denka Co., Ltd. Specific examples of the nonionic reactive surfactant include: alkyl ether-based reactive surfactants, such as products available under the product names “ADEKA REASOAP ER-10”, “ADEKA REASOAP ER-20”, “ADEKA REASOAP ER-30”, and “ADEKA REASOAP ER-40” from Asahi Denka Co., Ltd., and products available under the product names “LATEMUL PD-420”, “LATEMUL PD-430”, and “LATEMUL PD-450” from Kao Corporation; alkylphenyl ether-based or alkylphenyl ester-based reactive surfactants, such as products available under the product names “AQUALON RN-10”, “AQUALON RN-20”, “AQUALON RN-30”, and “AQUALON RN-50” from DKS Co. Ltd., and products available under the product names “ADEKA REASOAP NE-10”, “ADEKA REASOAP NE-20”, “ADEKA REASOAP NE-30”, and “ADEKA REASOAP NE-40” from Asahi Denka Co., Ltd.; and (meth)acrylate sulfuric acid ester-based reactive surfactants, such as products available under the product names “RMA-564”, “RMA-568”, and “RMA-1114” from Nippon Nyukazai Co., Ltd.

The anionic reactive surfactant is preferably used as the reactive surfactant. The anionic reactive surfactant is preferred because the surfactant is excellent in polymerization stability in many cases, and from the viewpoints of particle stability and appearance. The anionic reactive surfactant and the nonionic reactive surfactant may be used in combination.

In at least one embodiment of the present disclosure, the reactive surfactant preferably has a concentration of a SO₄²⁻ ion of 100 μg/g or less. In addition, the reactive surfactant is preferably an ammonium salt-type surfactant. The pressure-sensitive adhesive tape according to at least one embodiment of the present disclosure may be a pressure-sensitive adhesive tape to be used in a processing process for a semiconductor wafer. Accordingly, an impurity ion in the pressure-sensitive adhesive may be a problem. Accordingly, the content of the impurity ion in the pressure-sensitive adhesive is preferably as low as possible. When the concentration of the SO₄²⁻ ion falls within the above-mentioned range, and when the ammonium salt-type surfactant is used, adverse effects of the impurity ion can be prevented. Any appropriate method, such as an ion-exchange resin method, a membrane separation method, or a method of precipitating and filtering an impurity with an alcohol, may be used as a method of reducing or removing the impurity ion.

The reactive surfactant is used in any appropriate amount. The content of the reactive surfactant is preferably from 0.1 part by weight to 5 parts by weight, more preferably from 0.5 part by weight to 3 parts by weight with respect to 100 parts by weight of the monomer composition. When the content of the reactive surfactant is more than 5 parts by weight with respect to 100 parts by weight of the monomer composition, in the case where the pressure-sensitive adhesive composition is used for a pressure-sensitive adhesive tape for semiconductor wafer processing, a small element piece may be peeled from the pressure-sensitive adhesive tape in a dicing step or a subsequent step. In addition, when the content of the reactive surfactant is less than 0.1 part by weight with respect to 100 parts by weight of the monomer composition, a stable emulsion state may not be maintained.

In addition, the reactive surfactant and a surfactant free of any radically polymerizable functional group may be used in combination. Examples of the surfactant free of any radically polymerizable functional group include: anionic surfactants or nonionic anionic surfactants, such as sodium lauryl sulfate, ammonium lauryl sulfate, sodium dodecylbenzene sulfonate, a sodium polyoxyethylene alkyl ether sulfate, an ammonium polyoxyethylene alkylphenyl ether sulfate, a sodium polyoxyethylene alkylphenyl ether sulfate, and a sodium polyoxyethylene alkyl sulfosuccinate; and nonionic surfactants, such as a polyoxyethylene alkyl ether, a polyoxyethylene alkylphenyl ether, a polyoxyethylene fatty acid ester, and a polyoxyethylene polyoxypropylene block polymer. Those surfactants may be used alone or in combination thereof.

### A-3-3. Method of Polymerizing Water-Dispersed Acrylic Polymer

The water-dispersed acrylic polymer may be polymerized by any appropriate method. For example, the water-dispersed acrylic polymer may be obtained by adding water such as ion-exchanged water, a monomer composition, a surfactant, a polymerization initiator, and any appropriate additive to a reaction vessel, followed by mixing, and performing emulsion polymerization. When the water-dispersed acrylic polymer is a core-shell polymer, the water-dispersed acrylic polymer serving as a core-shell polymer may be obtained, for example, by: loading and mixing a monomer composition containing monomers for forming a core portion, water, a surfactant, a polymerization initiator, and any appropriate additive in a reaction vessel, followed by emulsion polymerization to form polymer particles serving as a core portion; and then loading and mixing a monomer composition containing monomers for forming a shell portion, water, a surfactant, a polymerization initiator, and any appropriate additive in the reaction vessel, followed by emulsion polymerization to form a shell portion. Examples of the any appropriate additive include a chain transfer agent and a silane coupling agent.

Any appropriate polymerization initiator may be used as the polymerization initiator. Examples thereof include: azo-based polymerization initiators, such as 2,2′-azobisisobutyronitrile, 2,2′-azobis(2-amidinopropane)dihydrochloride, 2,2′-azobis [2-(5-methyl-2-imidazolin-2-yl) propane]dihydrochloride, 2,2′-azobis(2-methylpropionamidine) disulfate, and 2,2′-azobis(N,N′-dimethyleneisobutylamidine); persulfates, such as potassium persulfate and ammonium persulfate; peroxide-based polymerization initiators, such as benzoyl peroxide, t-butyl hydroperoxide, and hydrogen peroxide; and redox-based initiators each based on a combination of a peroxide and a reducing agent [e.g., redox-based polymerization initiators based on a combination of a peroxide and ascorbic acid (e.g., a combination of hydrogen peroxide water and ascorbic acid), a combination of a peroxide and an iron (II) salt (e.g., a combination of hydrogen peroxide water and an iron (II) salt), and a combination of a persulfate and sodium hydrogen sulfite]. The polymerization initiators may be used alone or in combination thereof.

The polymerization initiator may be used in any appropriate amount in accordance with, for example, the kind of the polymerization initiator to be used and the composition of the monomer composition. The content of the polymerization initiator is, for example, from 0.01 part by weight to 1 part by weight, preferably from 0.02 part by weight to 0.5 part by weight with respect to 100 parts by weight of the monomer composition.

The chain transfer agent may be used for, for example, adjusting the molecular weight of the water-dispersed acrylic polymer. Any appropriate chain transfer agent may be used as the chain transfer agent. Specific examples thereof include lauryl mercaptan, glycidyl mercaptan, mercaptoacetic acid, 2-mercaptoethanol, thioglycolic acid, 2-ethylhexyl thioglycolate, and 2,3-dimercapto-1-propanol. The chain transfer agents may be used alone or in combination thereof. The content of the chain transfer agent is typically from 0.001 part by weight to 0.5 part by weight with respect to 100 parts by weight of the monomer composition.

The water-dispersed acrylic polymer is obtained by subjecting the monomer composition, the reactive surfactant, the polymerization initiator, and any appropriate additive such as the chain transfer agent to emulsion polymerization. Accordingly, the water-dispersed acrylic polymer may be prepared in the form of an emulsion. Any appropriate method may be used as a method for the emulsion polymerization. A specific example thereof is an emulsion polymerization method utilizing a general method, such as a collective loading method (collective polymerization method), a monomer dropping method, or a monomer emulsion dropping method. When a monomer or the like is dropped, the monomer may be continuously dropped or may be dividedly dropped. A polymerization temperature may be set to any appropriate value in accordance with, for example, the kind of the polymerization initiator, and may be set to, for example, the range of 5° C. to 100° C. In addition, an alkali aqueous solution, such as ammonia water, any of various water-soluble amines, a sodium hydroxide aqueous solution, or a potassium hydroxide aqueous solution, is preferably further added to a solution of the water-dispersed acrylic polymer obtained by the emulsion polymerization to adjust the pH to, for example, from 6 to 11, preferably from 7 to 10.

The gel fraction of the water-dispersed acrylic polymer is preferably 50 wt % or more, more preferably 70 wt % or more. When the gel fraction of the water-dispersed acrylic polymer is less than 50 wt %, a pressure-sensitive adhesive strength after the active energy ray irradiation is hardly reduced, and the contamination of an adherend with a sol content is liable to occur. The gel fraction of the water-dispersed acrylic polymer is, for example, 99 wt % or less. The gel fraction of the water-dispersed acrylic polymer may be determined by any appropriate method. For example, the gel fraction may be determined as an insoluble content with respect to a solvent such as ethyl acetate. Specifically, the gel fraction is determined as the weight fraction (unit: wt %) of an insoluble component after the immersion of the water-dispersed acrylic polymer in ethyl acetate at 23° C. for 7 days with respect to a sample before the immersion.

### A-3-4. Active Energy Ray-Curable Resin

Any appropriate resin that can be cured by an active energy ray such as UV light may be used as the active energy ray-curable resin. Specifically, an active energy ray-curable resin having a HSP value distance between the resin and the acrylic polymer to be used in the pressure sensitive adhesive of 8 or less is preferably used. A UV-curable resin is preferably used as the active energy ray-curable resin. For example, a UV-curable monomer and/or oligomer may be used as the UV-curable resin. Examples of the UV-curable monomer include urethane (meth)acrylate, trimethylolpropane tri(meth)acrylate, tetramethylolmethane tetra(meth)acrylate, pentaerythritol tri(meth)acrylate, dipentaerythritol dipentaerythritol monohydroxy penta(meth)acrylate, hexa(meth)acrylate, and 1, 4-butanediol di(meth)acrylate. The urethane (meth)acrylate may be self-emulsifiable urethane pentaerythritol tetra(meth)acrylate, (meth)acrylate. Examples of the UV-curable oligomer include a urethane-based oligomer, a polyether-based oligomer, a polyester-based oligomer, a polycarbonate-based oligomer, and a polybutadiene-based oligomer. An oligomer having a molecular weight of about 100 to about 30,000 is preferably used as the oligomer. The monomers and the oligomers may be used alone or in combination thereof. The active energy ray-curable resin may be emulsified with any appropriate surfactant or self-emulsifiable urethane (meth)acrylate as required. When the emulsification is performed, the preparation of the water-dispersed pressure-sensitive adhesive can be easily performed.

The active energy ray-curable resin is preferably urethane (meth)acrylate. The urethane (meth)acrylate has satisfactory compatibility with a (meth)acrylic polymer that may be used as a base polymer of the pressure-sensitive adhesive, and tends to have a low glass transition temperature. When the urethane (meth)acrylate is used, the pressure-sensitive adhesive strength before the active energy ray irradiation can be further improved. A resin obtained by emulsifying a polyfunctional monomer with the urethane (meth)acrylate is known as the active energy ray-curable resin. In at least one embodiment of the present disclosure, the content ratio of the urethane (meth)acrylate with respect to the entire amount of the active energy ray-curable resin is preferably as high as possible. The content ratio of the urethane (meth)acrylate with respect to the entire amount of the active energy ray-curable resin is preferably 80 wt % or more, more preferably 85 wt % or more, still more preferably 90 wt % or more, even still more preferably 95 wt % or more, particularly preferably 98 wt % or more. In at least one embodiment of the present disclosure, the content ratio of the urethane (meth)acrylate with respect to the entire amount of the active energy ray-curable resin may be 100 wt %. The polyfunctional monomer is a low-molecular weight component, and hence when the amount of the polyfunctional monomer is large, the polyfunctional monomer is unable to contribute to active energy ray (e.g., UV) curing and may remain as a residual monomer. The remaining polyfunctional monomer is liable to be transferred to the adherend and thus may cause the contamination of the adherend. The urethane (meth)acrylate has a high molecular weight, and hence even when the urethane (meth)acrylate is unable to contribute to the active energy ray curing and remains, its transfer to the adherend can be prevented.

A commercially available product may be used as the active energy ray-curable resin. Examples thereof include a product available under the product name “SHIKOH (trademark) UT-7119” from Mitsubishi Chemical Corporation, a product available under the product name “WUA-2” from DKS Co. Ltd., and a product available under the product name “ETERNACOLL UW-9102” from UBE Corporation. In addition, a product available under the product name “SHIKOH (trademark) UT-7119” from Mitsubishi Chemical Corporation serving as a commercially available product containing an active energy ray-curable resin and a photopolymerization initiator may be used. The active energy ray-curable resin having a HSP value distance between the resin and the acrylic polymer to be used for the pressure-sensitive adhesive of 8 or less may be selected also as each of those active energy ray-curable resins.

The active energy ray-curable resin may be used in any appropriate amount in accordance with, for example, the kind of the water-dispersed acrylic polymer. The amount is, for example, preferably from 5 parts by weight to 200 parts by weight, more preferably from 20 parts by weight to 150 parts by weight, still more preferably from 50 parts by weight to 150 parts by weight with respect to 100 parts by weight of the water-dispersed acrylic polymer.

### A-3-5. Photopolymerization Initiator

Any appropriate initiator may be used as the photopolymerization initiator. Examples of the photopolymerization initiator include: acyl phosphine oxide-based photopolymerization initiators, such as ethyl 2,4,6-trimethylbenzylphenyl phosphinate and (2,4,6-trimethylbenzoyl)-phenylphosphine oxide; α-ketol-based compounds, such as 4-(2-hydroxyethoxy)phenyl (2-hydroxy-2-propyl) ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; and acyl phosphonates, and α-hydroxyacetophenones such as 2-hydroxy-1-(4-(4-(2-hydroxy-2-methylpropionyl)benzyl)phenyl)-2-methylpropane-1. The photopolymerization initiators may be used alone or in combination thereof. A photopolymerization initiator that is liquid at room temperature (e.g., 23° C.) is preferably used because the photopolymerization initiator is soluble in (compatible with) the water-dispersed acrylic polymer solution.

A commercially available product may be used as the photopolymerization initiator. Examples thereof include products available under the product names “Omnirad 127D”, “Omnirad TPO-L”, “Omnirad TPO”, “Omnirad 651”, “Omnirad 184”, and “Omnirad 500” from IGM Resins B.V.

The photopolymerization initiator may be used in any appropriate amount. The content of the photopolymerization initiator is preferably from 0.5 part by weight to 20 parts by weight, more preferably from 1 part by weight to 10 parts by weight with respect to 100 parts by weight of the water-dispersed acrylic polymer. When the content of the photopolymerization initiator is less than 0.5 part by weight, the water-dispersed pressure-sensitive adhesive composition may not be sufficiently cured at the time of the active energy ray irradiation. When the content of the photopolymerization initiator is more than 20 parts by weight, the storage stability of the water-dispersed pressure-sensitive adhesive composition may be reduced.

### A-3-6. Cross-Linking Agent

In at least one embodiment of the present disclosure, the pressure-sensitive adhesive composition may further contain a cross-linking agent. When the cross-linking agent is used, the gel fraction of the pressure-sensitive adhesive composition can be adjusted. Any appropriate cross-linking agent may be used as the cross-linking agent. Examples thereof include bifunctional or higher epoxy-based cross-linking agents, isocyanate-based cross-linking agents, carbodiimide-based cross-linking agents, oxazoline-based cross-linking agents, aziridine-based cross-linking agents, melamine resin-based cross-linking agents, metal chelate-based cross-linking agents, peroxide-based cross-linking agents, and hydrazine-based cross-linking agents. The cross-linking agents may be used alone or in combination thereof.

Specific examples of the cross-linking agent include: epoxy-based cross-linking agents, such as N,N,N′,N′-tetraglycidyl-m-xylenediamine, 1,3-bis(N,N-glycidylaminomethyl)cyclohexane, and 1,6-hexanediol diglycidyl ether; isocyanate-based cross-linking agents (e.g., blocked isocyanate-based cross-linking agents) such as tolylene diisocyanate (blocked); carbodiimide-based cross-linking agents such as a product available under the product name “CARBODILITE V-01” (from Nisshinbo Chemical Inc.); epoxy-based cross-linking agents, such as polyethylene glycol diglycidyl ether and polyglycerol polyglycidyl ether; water-dispersed isocyanate-based cross-linking agents such as a product available under the product name “ELASTRON BN-69” (from DKS Co. Ltd.); oxazoline-based cross-linking agents such as a product available under the product name “EPOCROS WS-500” (from Nippon Shokubai Co., Ltd.); aziridine-based cross-linking agents such as a product available under the product name “CHEMITITE PZ-33” (from Nippon Shokubai Co., Ltd.); hydrophilically treated carbodiimide-based cross-linking agents such as products available under the product names “CARBODILITE V-02” and “CARBODILITE V-04” (from Nisshinbo Chemical Inc.); cross-linking agents each having an active methylol group or an active alkoxymethyl group including an active methylol such as hexamethylolmelamine and active an alkoxymethyl such as hexamethoxymethylmelamine; metal chelate-based cross-linking agents such as a product available under the product name “ORGATIX AI135” (from Matsumoto Pharm. Ind. Co., Ltd.); and hydrazine-based cross-linking agents, such as adipic dihydrazide and phthalic dihydrazide.

The content of the cross-linking agent is, for example, from 0.01 part by weight to 10 parts by weight, preferably from 0.05 part by weight to 5 parts by weight, more preferably from 0.1 part by weight to 3 parts by weight with respect to 100 parts by weight of the acrylic polymer. As described above, the water-dispersed pressure-sensitive adhesive composition may be free of any cross-linking agent (that is, the content of the cross-linking agent may be 0 parts by weight).

### A-3-7. Additive

The pressure-sensitive adhesive may contain any appropriate additive as required. Examples of the additive include a catalyst (e.g., a platinum catalyst), a tackifier, a plasticizer, a pigment, a dye, a filler, an age resistor, a conductive material, a UV absorber, a light stabilizer, a peeling modifier, a softener, a flame retardant, and a solvent. The additive is used in any appropriate amount in accordance with purposes.

The thickness of the pressure-sensitive adhesive layer may be set to any appropriate value. The thickness of the pressure-sensitive adhesive layer is preferably from 2 μm to 200 μm, more preferably from 3 μm to 150 μm, still more preferably from 5 μm to 100 μm. When the thickness of the pressure-sensitive adhesive layer falls within the above-mentioned ranges, a sufficient pressure-sensitive adhesive strength to an adherend can be exhibited.

### B. Method of Producing Pressure-Sensitive Adhesive Tape

The pressure-sensitive adhesive tape according to at least one embodiment of the present disclosure may be produced by any appropriate method. The pressure-sensitive adhesive tape may be obtained, for example, by: applying the pressure-sensitive adhesive to a release liner, followed by drying to form the pressure-sensitive adhesive layer on the release liner; and then transferring the pressure-sensitive adhesive layer to the base material. In addition, the pressure-sensitive adhesive tape may be obtained by applying the pressure-sensitive adhesive onto the base material, followed by drying. Various methods, such as bar coating, air knife coating, gravure coating, gravure reverse coating, reverse roll coating, lip coating, die coating, dip coating, offset printing, flexographic printing, and screen printing, may each be adopted as a method of applying the pressure-sensitive adhesive. Any appropriate method may be adopted as a method for the drying.

### C. Application of Pressure-sensitive Adhesive Tape

The pressure-sensitive adhesive tape according to at least one embodiment of the present disclosure can be suitably used in a production process for a semiconductor wafer. The pressure-sensitive adhesive tape can be used as, for example, a dicing tape or a backgrinding tape. As described above, the pressure-sensitive adhesive tape according to at least one embodiment of the present disclosure appropriately holds the adherend before the active energy ray irradiation, and the pressure-sensitive adhesive tape can be peeled without breakage of the adherend after the active energy ray irradiation even when the adherend is a micro and/or thin layer. Accordingly, the pressure-sensitive adhesive tape can also be suitably used in the processing of a semiconductor wafer having a thinner and more complicated structure.

### EXAMPLES

The present disclosure is specifically described below by way of Examples, but the present disclosure is not limited to these Examples. In addition, “part(s)” and “%” in Examples are by weight unless otherwise stated.

### [Synthesis Example 1] Synthesis of Acrylic Polymer A

180 Parts by weight of water, 58 parts by weight of 2-ethylhexyl acrylate (2EHA), 27 parts by weight of methyl methacrylate (MMA), 10 parts by weight of a carboxyl group-containing monomer (HOA-MS) (2-acryloyloxyethyl succinate, manufactured by Kyoeisha Chemical Co., Ltd., product name: “HOA-MS”), 5 parts by weight of 4-hydroxybutyl acrylate (4HBA) (manufactured by Osaka Organic Chemical Industry Ltd., product name: “4-HBA”), and 5 parts by weight of a reactive surfactant (manufactured by DKS Co. Ltd., product name: “AQUALON KH-1025”) were mixed in a reaction vessel including a condenser, a nitrogen-introducing tube, a temperature gauge, and a stirring device, and the mixture was stirred and emulsified with a homomixer. Next, while the emulsion was stirred, the reaction vessel was purged with nitrogen for 1 hour. Subsequently, an inner bath temperature during polymerization was controlled to 60° C. 0.02 Part by weight of a water-soluble azo initiator (manufactured by FUJIFILM Wako Pure Chemical Corporation, product name: “VA-057”) was added thereto to initiate the polymerization. Heating was performed for 2 hours. Thus, a core portion was produced.

Next, 180 parts by weight of water, 24 parts by weight of 2EHA, 56 parts by weight of MMA, 10 parts by weight of HOA-MS, 5 parts by weight of 4HBA, 5 parts by weight of acryloylmorpholine (ACMO), and 0.71 part by weight of the reactive surfactant (manufactured by DKS Co. Ltd., product name: “AQUALON KH-1025”) were mixed, and the mixture was stirred with a homomixer to produce a monomer emulsion for a shell. 0.10 Part by weight of the water-soluble azo initiator (manufactured by FUJIFILM Wako Pure Chemical Corporation, product name: “VA-057”) was added to the water-dispersed solution having dispersed therein the core particles. After an induction time period of 10 minutes, the emulsified monomer emulsion solution for a shell was added over 2 hours, and an aging reaction was further performed for 2 hours. Thus, a core-shell type water-dispersed acrylic polymer A was produced.

### [Synthesis Examples 2 and 3] Synthesis of Acrylic Polymers B and C

Core-shell type water-dispersed acrylic polymers B and C were each obtained in the same manner as in Synthesis Example 1 except that the monomer compositions of the core portion and the shell portion were changed as shown in Table 1.

### [Synthesis Example 4] Synthesis of Acrylic Polymer D

The monomer components shown in Table 1, 218 parts by weight of a solvent (ethyl acetate), and 0.3 part by weight of a BPO paste-N (manufactured by NOF Corporation, product name: “NYPER BW”) were mixed to provide a monomer composition. The resultant monomer composition was loaded into an experimental apparatus for polymerization obtained by mounting a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 1 hour. After that, while the composition was stirred under a stream of nitrogen, the composition was held at 65° C. for 4 hours, and was then held at 75° C. for 2 hours to be subjected to polymerization. Thus, a resin solution (prepolymer) was obtained.

Next, the resultant resin solution was cooled to room temperature. After that, 42.6 parts by weight of 2-isocyanatoethyl methacrylate (manufactured by Showa Denko K.K., product name: “Karenz MOI”) serving as a compound having a polymerizable carbon-carbon double bond was added to the resin solution. Further, 0.22 part by weight of dibutyltin (IV) dilaurate (manufactured by Wako Pure Chemical Industries, Ltd.) was loaded into the mixture, and the mixture was stirred under an air atmosphere at 50° C. for 24 hours. After that, ethyl acetate was added to the mixture. Thus, the acrylic polymer D (solid content: 30%) was obtained.

TABLE 1

| | | | A | B | C | D |
|---|---|---|---|---|---|---|
| Aqueous | Core | 2EHA | 58 | 70 | 50 | — |
| | (part(s) by | MMA | 27 | 15 | 35 | — |
| | weight) | HOA-MS | 10 | 10 | 10 | — |
| | | 4HBA | 5 | 5 | 5 | — |
| | | KH-1025 | 5 | 3 | 3 | — |
| | Shell | 2EHA | 24 | 30 | 50 | — |
| | (part(s) by | MMA | 56 | 50 | 35 | — |
| | weight) | HOA-MS | 10 | 10 | 10 | — |
| | | 4HBA | 5 | 5 | 5 | — |
| | | ACMO | 5 | 5 | — | — |
| | | KH-1025 | 0.71 | 1 | 1 | — |

| | | | | |
|---|---|---|---|---|
| Core/shell ratio | 30/70 | 50/50 | 50/50 | — |

| Solvent-based | BA | — | — | — | 100 |
|---|---|---|---|---|---|
| (part(s) by weight) | EA | — | — | — | 78 |
| | HEA | — | — | — | 40 |

| | | | | | |
|---|---|---|---|---|---|
| Initiator | Emulsion (core/shell) | 0.02/0.1 | 0.02/0.1 | 0.02/0.1 | — |
| (part(s) by weight) | Solvent | — | — | — | 0.3 |
| Tg | Emulsion (core/shell) | −35.4/19.4 | −49.9/8.1 | −24.6/−24.6 | — |
| | Solvent | — | — | — | −36.6 |

2EHA: 2-ethylhexyl acrylate
MMA: methyl methacrylate
HOA-MS: manufactured by Kyoeisha Chemical Co., Ltd., product name: “HOA-MS(N)” (2-acryloyloxyethyl succinate)
4HBA: manufactured by Osaka Organic Chemical Industry Ltd., product name: “4-HBA” (4-hydroxybutyl acrylate)
KH-1025: surfactant, manufactured by DKS Co. Ltd., product name: “AQUALON KH-1025”
ACMO: acryloylmorpholine
BA: butyl acrylate
EA: ethyl acrylate
HEA: 2-hydroxyethyl acrylate

### Example 1

100 Parts by weight of the water-dispersed acrylic polymer A, 140 parts by weight of a UV-curable resin (manufactured by Mitsubishi Chemical Corporation, product name: “SHIKOH (trademark) UT-7119”), and 3 parts by weight of a photopolymerization initiator (manufactured by IGM Resins B.V., product name: “Omnirad TPO-L”) were loaded and mixed. After that, the mixture was neutralized with 10% ammonia water to provide the water-dispersed pressure-sensitive adhesive composition.

The resultant water-dispersed pressure-sensitive adhesive composition was applied to a silicone release treatment surface of a polyester film (thickness: 38 μm) subjected to silicone release treatment so that its thickness after drying became 10 μm. The resultant was dried at 125° C. for 3 minutes to form the pressure-sensitive adhesive layer. Next, the base material (manufactured by Mitsubishi Chemical Corporation, product name: “T912E50” (easy-adhesion polyethylene terephthalate (PET) film (thickness: 50 μm)) was bonded to the pressure-sensitive adhesive surface of the pressure-sensitive adhesive layer so that the pressure-sensitive adhesive layer was transferred. Thus, the pressure-sensitive adhesive tape was produced.

### Examples 2 to 4

Pressure-sensitive adhesive tapes were obtained in the same manner as in Example 1 except that the compositions of the pressure-sensitive adhesive compositions were changed as shown in Table 2.

### Comparative Examples 1 to 3

The pressure-sensitive adhesive tapes were obtained in the same manner as in Example 1 except that the compositions of the pressure-sensitive adhesive compositions were changed as shown in Table 2.

### Comparative Example 4

100 Parts by weight of a solid content of the acrylic polymer D, 3 parts by weight of a cross-linking agent (manufactured by Mitsui Chemicals, Inc., product name: “TAKENATE D101-A”), 0.2 part by weight of a photopolymerization initiator (manufactured by IGM Resins B.V., product name: “Omnirad 127D”), 1.6 parts by weight of an additive 1 (manufactured by NOF Corporation, product name: “MODIPER (trademark) AS100”), and 0.2 part by weight of an additive 2 (manufactured by NOF Corporation, product name: “UNIOL D-1200”) were mixed to provide a pressure-sensitive adhesive composition.

The pressure-sensitive adhesive tape was obtained in the same manner as in Example 1 except that the resultant pressure-sensitive adhesive composition was used instead of the aqueous pressure-sensitive adhesive composition.

### Evaluation

The following evaluations were performed by using the water-dispersed acrylic polymers used in Examples and Comparative Examples and the resultant pressure-sensitive adhesive tapes. The results are shown in Table 2.

### 1. Glass Transition Temperature

The glass transition temperatures of the water-dispersed acrylic polymers obtained in Synthesis Examples 1 to 3 were each calculated from Fox's equation described below:

$$1 / Tg = \sum ( Wi / Tgi )$$

where Tg represents the glass transition temperature (unit: K) of the acrylic polymer, Wi represents the weight fraction (copolymerization ratio on a weight basis) of a monomer “i” in the acrylic polymer, and Tgi represents the glass transition temperature (unit: K) of the homopolymer of the monomer “i”.

The following values were used as the glass transition temperatures of homopolymers of monomers.

| | | |
|---|---|---|
| 2-Ethylhexyl acrylate | −70° | C. |
| Methyl methacrylate | 8° | C. |
| 2-Acryloyloxyethyl succinate | −40° | C. |
| 4-Hydroxybutyl acrylate | −40° | C. |
| N-Acryloylomorpholine | 145° | C. |
| Butyl acrylate | −55° | C. |
| Ethyl acrylate | −20° | C. |
| 2-Hydroxyethyl acrylate | −15° | C. |

### 2. Gel Fraction

The pressure-sensitive adhesive tape obtained in each of Examples or Comparative Examples was cut out into a size measuring 5 cm by 5 cm to provide a sample. The pressure-sensitive adhesive tape was irradiated with UV light (UV) (integrated light quantity: 460 mJ/cm² (365 nm conversion)) from the base material side. After that, the polyester film subjected to the release treatment was peeled from the sample. Next, about 0.1 part by weight of the sample was cut out from the sample after the irradiation with UV light. After that, the cut-out sample was wrapped with a porous polytetrafluoroethylene film (manufactured by Nitto Denko Corporation, product name: “NITOFLON (trademark) NTF1122”, porosity: 75%, thickness: 85 μm) having an average pore diameter of 0.2 μm whose weight had been measured in advance and a kite string (Wg₁) in a drawstring bag shape, and a total weight (Wg₂) was measured. Separately, the weight of the base material of the pressure-sensitive adhesive tape was calculated from its area and the specific gravity of a material for the base material (Wg₃). The bag was immersed in 50 mL of ethyl acetate and held at room temperature (about 23° C.) for 7 days so that only a sol component in the pressure-sensitive adhesive layer was eluted out of the film. After that, the bag was taken out from ethyl acetate, and ethyl acetate adhering to the outer surface of the bag was wiped off. Next, the bag was dried at 130° C. for 2 hours, and the weight (Wg₄) of the bag was measured. The measured values Wg₁ to Wg₄ were substituted into the following equation to calculate a gel fraction of the pressure-sensitive adhesive layer.

$$Gel fraction ( \% ) = [ ( {Wg}_{4} - {Wg}_{1} - {Wg}_{3} ) / ( {Wg}_{2} - {Wg}_{1} - {Wg}_{3} ) ]$$

### 3. Measurement of Molecular Weight of Sol Content

The entire amount of the soluble content collected at the time of the measurement of the gel fraction was collected into a screw tube. Next, the soluble content solution in the screw tube was left to stand at room temperature to be air-dried. After that, a solid content remaining in the screw tube was dissolved by adding tetrahydrofuran (THF) to the solid content so as to achieve concentration of 3.3 g/L and leaving the mixture to stand still for 1 day. After the solution had been filtered through a syringe filter, the molecular weight of the sol content was measured by a GPC method under the following conditions to produce a molecular weight distribution curve. In the resultant molecular weight distribution curve, the area ratio of a component having a weight-average molecular weight (Mw) of 1,000 or less was calculated. Measurement conditions: sample introduction amount: 500 mg, column temperature: 40° C., flow rate: 1.0 mL/min
Apparatus: manufactured by Tosoh Corporation, product name: “HLC-8320GPC”
Column: TSKgel GMHHR-H(S)

### 4. Pressure-Sensitive Adhesive Strength

A Si mirror wafer (manufactured by Shin-Etsu Chemical Co., Ltd.) was subjected to pretreatment involving washing with toluene, ethanol, and toluene in the stated order, and drying. Next, the pressure-sensitive adhesive layer of the pressure-sensitive adhesive tape of each of Examples or Comparative Examples was bonded to the wafer. The resultant was stored at normal temperature for 30 minutes. After that, a pressure-sensitive adhesive strength was measured under the following conditions (pressure-sensitive adhesive strength before UV). The pressure-sensitive adhesive tape was similarly bonded to the wafer, and the pressure-sensitive adhesive tape was irradiated with UV (integrated light quantity: 460 mJ/cm²) from its base material side with a high-pressure mercury lamp (UV irradiance: 70 mW/cm², manufactured by Nitto Seiki Co., Ltd., product name: “UM-810”) for about 10 seconds. Next, a pressure-sensitive adhesive strength was measured under the following conditions (pressure-sensitive adhesive strength after UV).

### <Pressure-Sensitive Adhesive Strength Measurement Conditions>

Tensile rate: 300 mm/min
Peel angle: 180° Temperature: 23° C.
Humidity: 50% RH
Tape width: 20 mm
Tape length: 80 mm

### 5. Particle Measurement

In a clean bench, the polyester film subjected to the release treatment was peeled from the pressure-sensitive adhesive tape obtained in each of Examples or Comparative Examples, and the pressure-sensitive adhesive layer side of the pressure-sensitive adhesive tape was bonded to an unused silicon mirror wafer (6 inches). After that, the pressure-sensitive adhesive tape was stored for 30 minutes. After that, the pressure-sensitive adhesive tape was irradiated with UV (integrated light quantity: 460 mJ/cm²) from its base material side with a high-pressure mercury lamp (UV irradiance: 70 mW/cm², manufactured by Nitto Seiki Co., Ltd., product name: “UM-810”) for about 10 seconds. Next, the pressure-sensitive adhesive tape was peeled from the silicon mirror wafer, and the number of particles on the surface of the silicon wafer was measured under the following conditions.

### <Measurement Conditions>

Measurement apparatus: wafer inspection apparatus Surfscan
SPSP1 (manufactured by KLA-Tencor Corporation)
Light source: argon ion laser (wavelength: 488 nm)
Laser irradiation angle: Normal (laser perpendicular irradiation)
Edge cut: 55 mm

Measured particle size range: The total number of particles measured in the range of 0.15 μm or more was defined as the number of particles.

### 6. HSP Value Distance

A solubility parameter (HSP value) was calculated by using HSPiP version 4.1.07 calculation software. The three parameters (δD, δP, and δH) of the Hansen solubility parameters of the acrylic polymer and the UV-curable resin used in each of Examples and Comparative Examples were measured by the following method.

In a sealable container, the acrylic polymer or the active energy ray-curable resin to be measured was loaded into a solvent so that a constant concentration was achieved. Cyclohexane, toluene, chloroform, 4-methyl-2-pentanone, ethyl acetate, cyclohexanone, 1,1,2,2-tetrabromoethane, acetone, N-methyl-2-pyrrolidone, benzyl alcohol, 1-butanol, acetic acid, 2-methoxy-ethanol, γ-butyrolactone, N,N-dimethylformamide, ethanol, N-methylformamide, ethanolamine, formamide, or 2-propanol was used as the solvent. Next, the container was shaken by hand so that the acrylic polymer or the active energy ray-curable resin and the solvent were sufficiently mixed. Next, the container was left to stand still under a room temperature environment (23° C.) for 24 hours. After that, the container was visually observed. A case in which a precipitate or an aggregate was present in the container was defined as “not dissolved” and a case in which the precipitate and the aggregate were absent therein was defined as “dissolved”. The test was performed on the respective solvents, and from the obtained test results, a sphere (Hansen sphere) that included coordinates of solvents, each of which had dissolved a target substance, and was free of coordinates of solvents, each of which had not dissolved the target substance, was drawn in a Hansen space. The obtained numerical value was input into the above-mentioned calculation software to calculate HSP values of the acrylic polymer and the UV-curable resin by the following equation.

$$HSP = √ ( δ D \hat{} 2 + δ P \hat{} 2 + δ H \hat{} 2 )$$

A distance between HSP values was calculated from the resultant HSP value of the acrylic polymer and HSP value of the active energy ray-curable resin with the above-mentioned calculation software.

TABLE 2

| | | | Exam- | Exam- | Exam- | Exam- | Exam- | Comparative | Comparative | Comparative | Comparative |
|---|---|---|---|---|---|---|---|---|---|---|---|
| | | | ple 1 | ple 2 | ple 3 | ple 4 | ple 5 | Example 1 | Example 2 | Example 3 | Example 4 |
| Composition | Polymer | A | 100 | 100 | 100 | — | — | — | 100 | 100 | — |
| of pressure- | (part(s) by | B | — | — | — | 100 | 100 | — | — | — | — |
| sensitive | weight) | C | — | — | — | — | — | 100 | — | — | — |
| adhesive | | D | — | — | — | — | — | — | — | — | 100 |
| composition | Light | 127D | — | — | 3 | 3 | 3 | 3 | — | — | 0.2 |
| | initiator | TPO-L | 3 | — | — | — | — | — | 3 | — | — |
| | (part(s) by | TPO | — | 3 | — | — | — | — | — | — | — |
| | weight) | | | | | | | | | | |
| | Cross- | TAKENATE | — | — | — | — | — | — | — | — | 3 |
| | linking agent | D-101-A | | | | | | | | | |
| | (part(s) by | | | | | | | | | | |
| | weight) | | | | | | | | | | |
| | UV-curable | UT-7119 | 140 | 100 | 100 | — | — | 100 | — | — | — |
| | resin | UW-9102 | — | — | — | — | — | — | 100 | — | — |
| | (part(s) by | WUA-3 | — | — | — | — | 140 | — | — | — | — |
| | weight) | sWK-213 | — | — | — | 140 | — | — | — | — | — |
| | UV-curable | UV-W300 | — | — | — | — | — | — | — | 100 | — |
| | resin + light | | | | | | | | | | |
| | initiator | | | | | | | | | | |
| | (part(s) by | | | | | | | | | | |
| | weight) | | | | | | | | | | |
| | Additive | AS100 | — | — | — | — | — | — | — | — | 1.6 |
| | (part(s) by | UNIOL D- | — | — | — | — | — | — | — | — | 0.2 |
| | weight) | 1200 | | | | | | | | | |

| 180° pressure-sensitive | Before UV | 0.3 | 0.4 | 0.3 | 2.8 | 5.7 | 2.2 | 6.4 | 0.3 | 0.5 |
|---|---|---|---|---|---|---|---|---|---|---|
| adhesive strength | After UV | 0.01 | 0.01 | 0.01 | 0.02 | 0.03 | 0.05 | 0.01 | 0.01 | 0.03 |
| (N/20 mm) | | | | | | | | | | |
| Gel fraction | Before UV | 15% | 32% | 33% | 13% | 16% | 42% | 45% | 37% | 87% |
| | After UV | 95% | 97% | 95% | 96% | 95% | 95% | 90% | 99% | 93% |

| | | | | | | | | | |
|---|---|---|---|---|---|---|---|---|---|
| HSP value distance | 6.0 | 6.0 | 6.0 | 7.0 | 4.6 | 11.8 | 8.3 | 10.3 | — |
| Ratio of component having Mw of | — | — | — | — | 4% | — | 28% | 38% | 25% |
| 1,000 or less in sol | | | | | | | | | |
| Total amount of particles (particles/ | 135 | 156 | 148 | 52 | 116 | 3,137 | 2,974 | 3,455 | 1,159 |
| 6 inch) | | | | | | | | | |

127D: manufactured by IGM Resins B.V., product name: “Omnirad 127D”
TPO-L: manufactured by IGM Resins B.V., product name: “Omnirad TPO-L”
TPO: manufactured by IGM Resins B.V., product name: “Omnirad TPO”
UT-7119: manufactured by Mitsubishi Chemical Corporation, product name: “SHIKOH (trademark) UT-7119”
UW-9102: manufactured by UBE Corporation, product name: “ETERNACOLL UW-9102”
UV-W300: manufactured by Mitsubishi Chemical Corporation, product name: “SHIKOH UV-W300”
WUA-3: manufactured by DKS Co. Ltd., product name: “WUA-3”
sWK-213: manufactured by Mitsubishi Chemical Corporation, product name: “sWK-213”
AS100: manufactured by NOF Corporation, product name: “MODIPER (trademark) AS100”
UNIOL D-1200: manufactured by NOF Corporation, product name: “UNIOL D-1200”

In each of the pressure-sensitive adhesive tapes of Examples of the present disclosure, the ratio of the component having a molecular weight 1,000 or less in the sol was 20% or less. In the pressure-sensitive adhesive tapes of Examples 1 to 4, the ratio of the component having a molecular weight of 1,000 or less in the sol content was 0%. The total amount of particles on the surface of the wafer serving as an adherend was reduced.

The pressure-sensitive adhesive tape according to at least one embodiment of the present disclosure can be suitably used in an application for semiconductor wafer processing.

What is claimed is:

1. A pressure-sensitive adhesive tape, comprising:
a base material; and
a pressure-sensitive adhesive layer formed of an active energy ray-curable pressure-sensitive adhesive,
wherein a ratio of a component having a weight-average molecular weight of 1,000 or less in a sol content of the pressure-sensitive adhesive layer after active energy ray irradiation is 20% or less, and
wherein a pressure-sensitive adhesive strength of the pressure-sensitive adhesive layer after the active energy ray irradiation is 0.04 N/20 mm or less.

2. The pressure-sensitive adhesive tape according to claim 1, wherein the active energy ray-curable pressure-sensitive adhesive is a water-dispersed pressure-sensitive adhesive.

3. The pressure-sensitive adhesive tape according to claim 2, wherein the active energy ray-curable pressure-sensitive adhesive contains a water-dispersed acrylic polymer and an active energy ray-curable resin.

4. The pressure-sensitive adhesive tape according to claim 3, wherein the active energy ray-curable resin contains urethane (meth)acrylate.

5. The pressure-sensitive adhesive tape according to claim 3, wherein a Hansen solubility parameter (HSP) value distance between the water-dispersed acrylic polymer and the active energy ray-curable resin is 8 or less.

6. The pressure-sensitive adhesive tape according to claim 1, wherein the pressure-sensitive adhesive tape is used for semiconductor wafer processing.
